(19) United States
(12) Patent Application Publication
(10) Pub. No.: US 2026/0360607 A1
(43) Pub. Date: Nov. 12, 2026

(54) MULTILAYER-TYPE ON-CHIP INDUCTOR STRUCTURE

(71) Applicant: VIA LABS, INC., New Taipei City (TW)

(72) Inventors: Sheng-Yuan LEE, New Taipei City (TW); Nien-Chi LIU, New Taipei City (TW)

(21) Appl. No.: 19/324,256

(22) Filed: Sep. 10, 2025

(30) Foreign Application Priority Data
May 7, 2025 (TW) 114117108

(51) Int. Cl. H01F 27/28; H01F 27/32

(52) U.S. Cl. CPC H01F 27/2804; H01F 27/323; H01F 27/2809

(57) ABSTRACT

A multilayer-type on-chip inductor structure is provided. The structure includes first to fourth semi-circular windings and fifth to eighth semi-circular windings thereunder disposed in a dielectric layer. The dielectric layer has an inductor region divided by a central line into first and second regions. The first, second, fifth, and sixth semi-circular windings are concentrically arranged in the first region, and the third, fourth, seventh, and eighth semi-circular windings are concentrically arranged in the second region. The first, seventh, second and eighth semi-circular windings are electrically connected in sequence, and the third, fifth, fourth and sixth semi-circular windings are electrically connected in sequence. As viewed from a top-view perspective, the third semi-circular winding is symmetrically arranged with the first semi-circular winding, and the third semi-circular winding partially overlaps the seventh semi-circular winding.

### CROSS REFERENCE TO RELATED APPLICATIONS

This application claims priority of Taiwan Patent Application No. 114117108, filed on May 7, 2025, and entitled “MULTILAYER-TYPE ON-CHIP INDUCTOR STRUCTURE”, the entirety of which is incorporated by reference herein.

### TECHNICAL FIELD

The present disclosure relates to a semiconductor structure, and, in particular, it relates to a multilayer-type on-chip inductor structure capable of reducing planar size.

### BACKBGOUND

Many digital/analog devices and circuits have been successfully applied to semiconductor integrated circuits. Such devices may include passive components, such as inductors, resistors, and capacitors. Typically, a semiconductor integrated circuit includes a silicon substrate. One or more dielectric layers are disposed on the substrate, with one or more metal layers disposed in the dielectric layers. The metal layers may be employed to form on-chip elements, such as on-chip inductors, using current semiconductor process technologies.

In such on-chip inductors, multi-layer metal layers in the dielectric layers are usually used as the windings of the spiral inductor. However, the inductance value of an inductor is usually proportional to the length of the windings of the inductor. Therefore, in order to achieve a higher inductance value, both the planar size of the inductor and its manufacturing costs must be increased.

Therefore, there is a need for a novel inductor structure that is capable of improving the aforementioned problems.

### BRIEF SUMMARY

An embodiment of the present disclosure provides a multilayer-type on-chip inductor structure. The multilayer-type on-chip inductor structure includes a dielectric layer, first to fourth semi-circular windings arranged at a first level of the dielectric layer, and fifth to eighth semi-circular windings arranged at a second level lower than the first level of the dielectric layer. The dielectric layer has an inductor region divided by a center line into a first region and a second region. The first and second semi-circular windings at the first level and the fifth and sixth semi-circular windings at the second level are arranged concentrically in the first region. The third and fourth semi-circular windings at the first level and the seventh and eighth semi-circular windings at the second level are arranged concentrically in the second region. The sixth semi-circular winding is connected to the eighth semi-circular winding. The first, seventh, second and eighth semi-circular windings are electrically connected in sequence, and the third, fifth, fourth and sixth semi-circular windings are electrically connected in sequence. As viewed from a top-view perspective, the third semi-circular winding is symmetrically arranged with the first semi-circular winding, and the third semi-circular winding partially overlaps the seventh semi-circular winding.

An embodiment of the present disclosure provides a multilayer-type on-chip inductor structure. The multilayer-type on-chip inductor structure includes a dielectric layer, first to fourth semi-circular windings arranged at a first level of the dielectric layer, fifth to eighth semi-circular windings arranged at a second level lower than the first level of the dielectric layer, and a first conductive layer arranged at the second level of the dielectric layer. The dielectric layer has an inductor region divided into a first region and a second region by a center line. The first, second, fifth and sixth semi-circular windings are in the first region, and the third, fourth, seventh and eighth semi-circular windings are in the second region. The first, seventh, second and eighth semi-circular windings are electrically connected in sequence, and the third, fifth, fourth and sixth semi-circular windings are electrically connected in sequence. As viewed from a top-view perspective, the third semi-circular winding is symmetrically arranged with the first semi-circular winding, and the third semi-circular winding partially overlaps the seventh semi-circular winding. Furthermore, the first conductive layer is disposed in the first region and the first conductive layer overlaps a portion of the second semi-circular winding and is electrically connected thereto.

### BRIEF DESCRIPTION OF THE DRAWINGS

The present disclosure can be more fully understood by reading the subsequent detailed description and examples with references made to the accompanying drawings, wherein:

FIG. 1 shows a plan view of a multilayer-type on-chip inductor structure in accordance with some embodiments of the present disclosure;

FIG. 2A shows a plan view of the arrangement of the upper windings in the multilayer-type on-chip inductor structure shown in FIG. 1 according to some embodiments of the present disclosure;

FIG. 2B shows a plan view of the arrangement of the lower windings in the multilayer-type on-chip inductor structure shown in FIG. 1 according to some embodiments of the present disclosure;

FIG. 3A shows a cross-sectional view along line 3A-3A’ in FIG. 1 according to some embodiments of the present disclosure;

FIG. 3B shows a cross-sectional view along line 3B-3B’ in FIG. 1 according to some embodiments of the present disclosure;

FIG. 4 shows a plan view of the multilayer-type on-chip inductor structure according to some embodiments of the present disclosure;

FIG. 5A shows a plan view of the arrangement of the upper windings in the multilayer-type on-chip inductor structure shown in FIG. 4 according to some embodiments of the present disclosure.

FIG. 5B shows a plan view of the arrangement of the lower windings in the multilayer-type on-chip inductor structure shown in FIG. 4 according to some embodiments of the present disclosure;

FIG. 6A shows a cross-sectional view along line 6A-6A’ in FIG. 4 according to some embodiments of the present disclosure;

FIG. 6B shows a cross-sectional view along line 6B-6B’ in FIG. 4 according to some embodiments of the present disclosure;

FIG. 7 shows a plan view of a multilayer-type on-chip inductor structure according to some embodiments of the present disclosure;

FIG. 8A shows a cross-sectional view along line 8A-8A’ in FIG. 7 according to some embodiments of the present disclosure;

FIG. 8B shows a cross-sectional view along line 8B-8B’ in FIG. 7 according to some embodiments of the present disclosure;

FIG. 9 shows a plan view of a multilayer-type on-chip inductor structure in accordance with some embodiments of the present disclosure;

FIG. 10A shows a cross-sectional view along line 10A-10A’ in FIG. 9 according to some embodiments of the present disclosure;

FIG. 10B shows a cross-sectional view along line 10B-10B’ in FIG. 9 according to some embodiments of the present disclosure;

FIG. 11 shows a plan view of a conventional on-chip inductor structure.

### DETAILED DESCRIPTION

The following description is made for the purpose of illustrating the general principles of the disclosure and should not be taken in a limiting sense. The scope of the disclosure is best determined by reference to the appended claims.

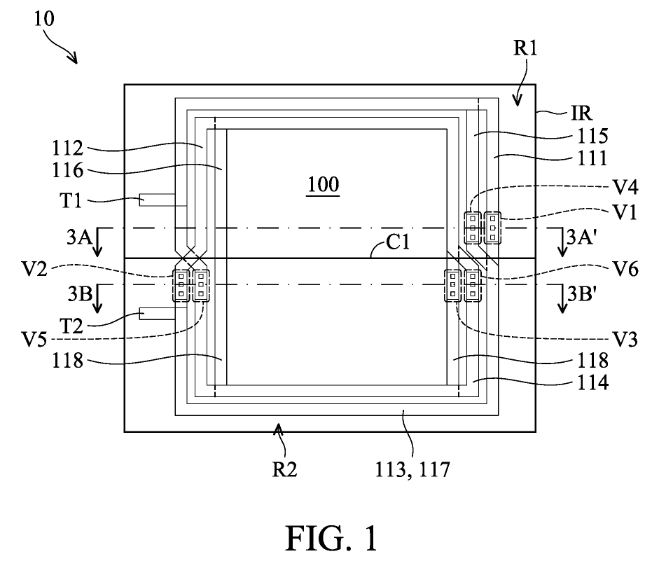

Refer to FIG. 1, which shows a plan view of a multilayer-type on-chip inductor structure 10 according to some embodiments of the present disclosure. In some embodiments, the multilayer-type on-chip inductor structure 10 includes a dielectric layer 100 disposed on a substrate (not shown). The substrate includes a silicon substrate or other semiconductor material substrate well known in the art. The substrate may include various components, such as transistors, resistors, capacitors, and other conventional semiconductor components. Furthermore, the substrate may also include other conductive layers (e.g., copper, aluminum, or alloys thereof) and one or more insulating layers (e.g., silicon oxide layers, silicon nitride layers, or low-k dielectric material layers).

In some embodiments, the dielectric layer 100 may be an intermetallic dielectric (IMD) layer formed over the substrate, which is a single dielectric material layer or a multilayer dielectric structure. For example, the intermetallic dielectric layer may include multiple dielectric material layers. The multiple dielectric material layers are usually formed over the substrate successively and alternately with multiple horizontal conductive features (e.g., conductive layers/metal layers). Furthermore, the horizontal conductive features are electrically connected to each other via vertical conductive features (e.g., conductive plugs) and form an interconnect structure with the dielectric layer 100 to electrically connect various components formed in or on the substrate. For example, the intermetallic dielectric layer may include a silicon oxide layer, a silicon nitride layer, a low-k dielectric material layer, or another suitable dielectric material layer.

In some embodiments, the multilayer-type on-chip inductor structure 10 further includes a plurality of semi-circular windings disposed in the dielectric layer 100. These windings constitute a multilayer-type on-chip inductor and are disposed in the inductor region IR of the dielectric layer 100, as shown in FIG. 1. In some embodiments, the multilayer-type on-chip inductor structure 10 includes a first semi-circular winding 111, a second semi-circular winding 112, a third semi-circular winding 113, a fourth semi-circular winding 114, a fifth semi-circular winding 115, a sixth semi-circular winding 116, a seventh semi-circular winding 117, and an eighth semi-circular winding 118.

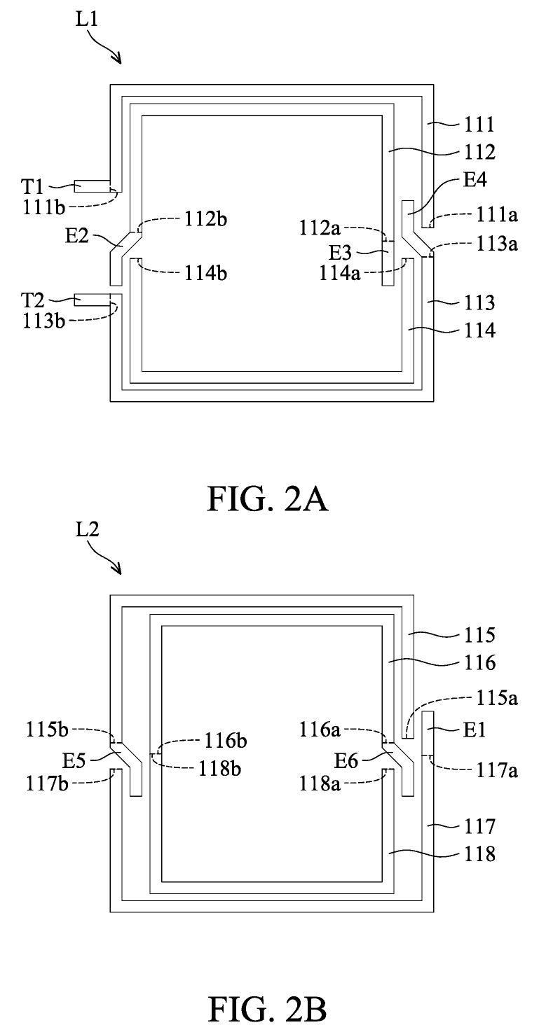

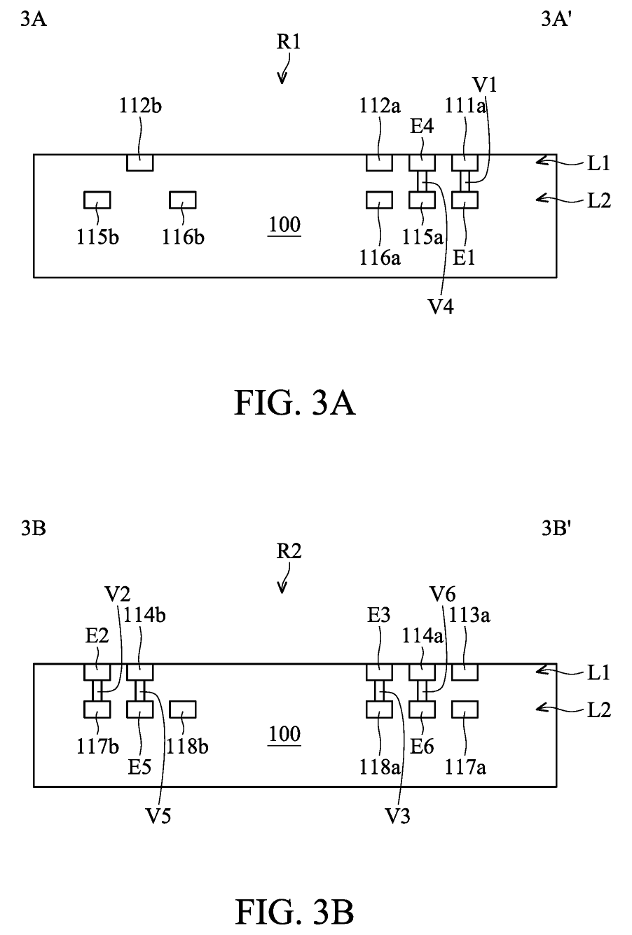

In some embodiments, the inductor region IR is divided into a first region R1 and a second region R2 by a center line C1. Furthermore, the first semi-circular winding 111 to the fourth semi-circular winding 114 are arranged at the first level L1 (or the upper level, as shown in FIGS. 2A, 3A and 3B) of the dielectric layer 100. The fifth semi-circular winding 115 to the eighth semi-circular winding 118 are arranged at the second level L2 (or the lower level, as shown in FIGS. 2B, 3A and 3B) lower than the first level L1 of the dielectric layer 100.

Refer to FIG. 2A, which illustrates a plan view of the arrangement of the upper windings in the multilayer-type on-chip inductor structure 10 shown in FIG. 1 according to some embodiments of the present disclosure. In some embodiments, the upper windings include the first semi-circular winding 111 and the second semi-circular winding 112 disposed in the first region R1 (shown in FIG. 1), and the third semi-circular winding 113 and the fourth semi-circular winding 114 disposed in the second region R2 (shown in FIG. 2). The upper windings are disposed at the first level L1 of the dielectric layer 100 (as shown in FIGS. 3A and 3B). The first semi-circular winding 111 and the second semi-circular winding 112 in the first region R1 are arranged concentrically with the center of the inductor region IR (shown in FIG. 1), and the third semi-circular winding 113 and the fourth semi-circular winding 114 in the second region R2 are arranged concentrically with the center of the inductor region IR.

Furthermore, each semi-circular winding has two end portions. For example, the first semi-circular winding 111 has two end portions 111a and 111b, and the second semi-circular winding 112 has two end portions 112a and 112b corresponding to the end portions 111a and 111b. Similarly, the third semi-circular winding 113 has two end portions 113a and 113b, and the fourth semi-circular winding 114 has two end portions 114a and 114b corresponding to the end portions 113a and 113b.

In some embodiments, the upper windings can be formed by the topmost horizontal conductive feature in the intermetallic dielectric layer (i.e., the dielectric layer 100), and are made of copper, aluminum, alloys thereof, or another suitable metal material.

Refer to FIG. 2B, which illustrates a plan view of the arrangement of the lower windings in the multilayer-type on-chip inductor structure 10 shown in FIG. 1 according to some embodiments of the present disclosure. In some embodiments, the lower windings include a fifth semi-circular winding 115 and a sixth semi-circular winding 116 disposed in the first region R1 (shown in FIG. 1), and a seventh semi-circular winding 117 and an eighth semi-circular winding 118 disposed in the second region R2 (shown in FIG. 1). The lower windings are disposed at the second level L2 of the dielectric layer 100 (as shown in FIGS. 3A and 3B). The fifth semi-circular winding 115 and the sixth semi-circular winding 116 are arranged concentrically with the center of the inductor region (shown in FIG. 1) IR in the first region R1, and the seventh semi-circular winding 117 and the eighth semi-circular winding 118 are arranged concentrically with the center of the inductor region IR in the second region R2. Furthermore, the fifth semi-circular winding 115 has two end portions 115a and 115b, and the sixth semi-circular winding 116 has two end portions 116a and 116b corresponding to the end portions 115a and 115b. Similarly, the seventh semi-circular winding 117 has two end portions 117a and 117b, and the eighth semi-circular winding 118 has two end portions 118a and 118b corresponding to the end portions 117a and 117b.

In some embodiments, the lower windings can be formed by the horizontal conductive features of the second topmost layer (next to the horizontal conductive features of the topmost layer) in the intermetallic dielectric layer (i.e., dielectric layer 100), and are made of copper, aluminum, alloys thereof, or another suitable metal material.

Refer to FIGS. 3A and 3B. FIG. 3A shows a cross-sectional view along line 3A-3A’ in FIG. 1 according to some embodiments of the present disclosure, and FIG. 3B shows a cross-sectional view along line 3B-3B’ in FIG. 1 according to some embodiments of the present disclosure. At the same time, refer to FIGS. 1, 2A, and 2B. In some embodiments, the upper windings and the lower windings of the multilayer-type on-chip inductor structure 10 are electrically and/or physically connected in a different winding method from that of traditional spiral/symmetrical inductors.

More specifically, in some embodiments, the first semi-circular winding 111, the seventh semi-circular winding 117, the second semi-circular winding 112 and the eighth semi-circular winding 118 are electrically connected in sequence, and the third semi-circular winding 113, the fifth semi-circular winding 115, the fourth semi-circular winding 114 and the sixth semi-circular winding 116 are electrically connected in sequence. Next, the sixth semi-circular winding 116 and the eighth semi-circular winding 118 are connected to each other to form a spiral inductor element in the multilayer-type on-chip inductor structure 10. In some embodiments, the connected upper and lower windings have substantially circular, rectangular, hexagonal, octagonal, or polygonal shapes, as viewed from a top-view perspective. Herein, in order to simplify the diagram, a rectangle shape is depicted as an example for illustration.

In addition, in some embodiments, the third semi-circular winding 113 and the first semi-circular winding 111 are arranged symmetrically with the center line C1 (shown in FIG. 1) as the axis of symmetry, as viewed from a top-view perspective. The third semi-circular winding 113 partially overlaps the seventh semi-circular winding 117 on the projection plane. Furthermore, the sixth semi-circular winding 116 and the eighth semi-circular winding 118 are also arranged symmetrically with the center line C1 as the axis of symmetry. The sixth semi-circular winding 116 partially overlaps the second semi-circular winding 112 on the projection plane.

In some embodiments, the multilayer-type on-chip inductor structure 10 further includes a plurality of conductive extending portions and a plurality of plug structures for electrically and/or physically connecting the semi-circular windings in the upper windings with the semi-circular windings in the lower windings. The plurality of conductive extending portions may be formed of horizontal conductive features in the intermetallic dielectric layer (i.e., the dielectric layer 100), and the plurality of plug structures may include one or more conductive plugs, and each conductive plug may be formed of vertical conductive features in the intermetallic dielectric layer (i.e., the dielectric layer 100).

Refer to FIGS. 1, 2A, 2B and 3A. In some embodiments, a conductive extending portion E1 is disposed at the second level L2 of the dielectric layer 100, and it extends from the end portion 117a of the seventh semi-circular winding 117 at the second level L2 to the first region R1 along a straight line direction as viewed from a top-view perspective, so that the conductive extending portion E1 partially overlaps the end portion 111a of the first semi-circular winding 111 at the first level L1 on the projection plane. Furthermore, the plug structure V1 is disposed in the first region R1 of the dielectric layer 100. The plug structure V1 is disposed between the conductive extending portion E1 and the end portion 111a of the first semi-circular winding 111 and is connected thereto. As a result, the first semi-circular winding 111 is electrically connected to the seventh semi-circular winding 117.

A conductive extending portion E2 is disposed at the first level L1 of the dielectric layer 100, and extends from the end portion 112b of the second semi-circular winding 112 at the first level L1 to the second region R2 along the zigzag direction as viewed from a top-view perspective, so that the conductive extending portion E2 partially overlaps the end portion 117b of the seventh semi-circular winding 117 at the second level L2 on the projection plane. Furthermore, the plug structure V2 is disposed in the second region R2 of the dielectric layer 100. The plug structure V2 is disposed between the conductive extending portion E2 and the end portion 117b of the seventh semi-circular winding 117 and connected thereto. As a result, the seventh semi-circular winding 117 is electrically connected to the second semi-circular winding 112.

A conductive extending portion E3 is disposed at the first level L1 of the dielectric layer 100, and extends from the end portion 112a of the second semi-circular winding 112 at the first level L1 to the second region R2 along a straight line direction as viewed from a top-view perspective, so that the conductive extending portion E3 partially overlaps the end portion 118a of the eighth semi-circular winding 118 at the second level L2 on the projection plane. Furthermore, the plug structure V3 is disposed in the second region R2 of the dielectric layer 100. The plug structure V3 is disposed between the conductive extending portion E3 and the end portion 118a of the eighth semi-circular winding 118 and connected thereto. As a result, the second semi-circular winding 112 is electrically connected to the eighth semi-circular winding 118.

A conductive extending portion E4 is disposed at the first level L1 of the dielectric layer 100, and extends from the end portion 113a of the third semi-circular winding 113 at the first level L1 to the first region R1 along the zigzag direction as viewed from a top-view perspective, so that the conductive extending portion E4 partially overlaps the end portion 115a of the fifth semi-circular winding 115 at the second level L2 on the projection plane. Furthermore, the plug structure V4 is disposed in the first region R1 of the dielectric layer 100. The plug structure V4 is disposed between the conductive extending portion E4 and the end portion 115a of the fifth semi-circular winding 115 and is connected thereto. As a result, the third semi-circular winding 113 is electrically connected to the fifth semi-circular winding 115.

Next, refer to FIGS. 1, 2A, 2B and 3B. A conductive extending portion E5 is disposed at the second level L2 of the dielectric layer 100, and extends from the end portion 115b of the fifth semi-circular winding 115 at the second level L2 along the zigzag direction to the second region R2 as viewed from a top-view perspective, so that the conductive extending portion E5 partially overlaps the end portion 114b of the fourth semi-circular winding 114 at the first level L1 on the projection plane. Furthermore, the plug structure V5 is disposed in the second region R2 of the dielectric layer 100. The plug structure V5 is disposed between the conductive extending portion E5 and the end portion 114b of the fourth semi-circular winding 114 and connected thereto. As a result, the fifth semi-circular winding 115 is electrically connected to the fourth semi-circular winding 114.

A conductive extending portion E6 is disposed at the second level L2 of the dielectric layer 100, and extends from the end portion 116a of the sixth semi-circular winding 116 at the second level L2 to the second region R2 along the zigzag direction as viewed from a top-view perspective, so that the conductive extending portion E6 partially overlaps the end portion 114a of the fourth semi-circular winding 114 at the first level L1 on the projection plane. Furthermore, the plug structure V6 is disposed in the second region R2 of the dielectric layer 100. The plug structure V6 is disposed between the conductive extending portion E6 and the end portion 114a of the fourth semi-circular winding 114 and connected thereto. As a result, the fourth semi-circular winding 114 is electrically connected to the sixth semi-circular winding 116. Afterwards, the end portion 116b of the sixth semi-circular winding 116 and the end portion 118b of the eighth semi-circular winding 118 are connected to each other.

In some embodiments, the multilayer-type on-chip inductor structure 10 further includes a first input/output terminal portion T1 and a second input/output terminal portion T2 disposed at the first level L1. As shown in FIGS. 1 and 2A, the first input/output terminal portion T1 is disposed in the first region R1 of the dielectric layer 100 and extends outward and laterally from the end portion 111b of the first semi-circular winding 111. The second input/output terminal portion T2 is disposed in the second region R2 of the dielectric layer 100 and extends outward and laterally from the end portion 113b of the third semi-circular winding 113.

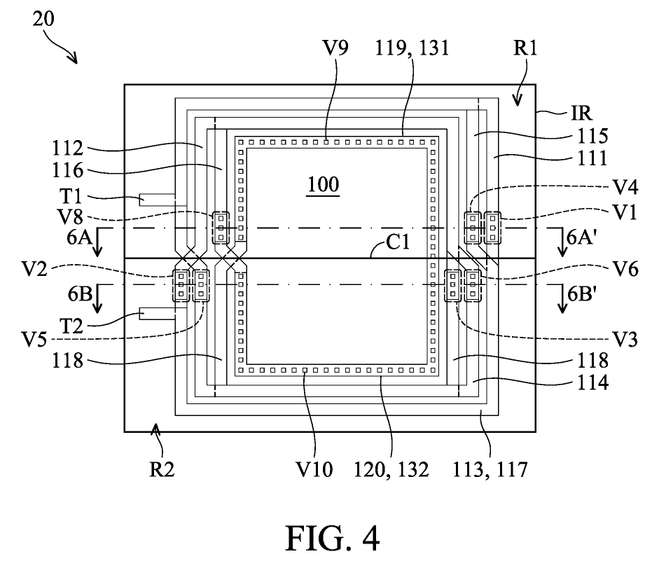

Refer to FIG. 4, which illustrates a plan view of a multilayer-type on-chip inductor structure 20 according to some embodiments of the present disclosure. Herein, elements in FIG. 4 that are the same as or similar to those of the multilayer-type on-chip inductor structure 10 in FIG. 1 are labeled with the same or similar reference numbers as in FIG. 1 and their descriptions may be omitted. In some embodiments, the multilayer-type on-chip inductor structure 20 is similar to the multilayer-type on-chip inductor structure 10 in FIG. 1. The difference is that the multilayer chip on-chip inductor structure 20 further includes a ninth semi-circular winding 119, a tenth semi-circular winding 120, a first semi-circular conductive layer 131, a second semi-circular conductive layer 132, and additional conductive extending portions and additional plug structures. The additional conductive extending portions and the additional plug structures are employed to electrically and/or physically connect the ninth semi-circular winding 119, the tenth semi-circular winding 120, the first semi-circular conductive layer 131, and the second semi-circular conductive layer 132.

In some embodiments, the ninth semi-circular winding 119 is disposed at the second level L2 of the dielectric layer 100 and is electrically connected to the eighth semi-circular winding 118. The tenth semi-circular winding 120 is disposed at the first level L1 of the dielectric layer 100 and is electrically connected to the sixth semi-circular winding 116. Furthermore, the ninth semi-circular winding 119 has two end portions 119a and 119b, and the tenth semi-circular winding 120 also has two end portions 120a and 120b respectively corresponding to the end portions 119a and 119b. The first semi-circular conductive layer 131 disposed at the first level L1 extends from the end portion 120a of the tenth semi-circular winding 120 to the first region R1, and the second semi-circular conductive layer 132 disposed at the second level L2 extends from the end portion 119a of the ninth semi-circular winding 119 to the second region R2.

In some embodiments, the first semi-circular winding 111, the second semi-circular winding 112, and the first semi-circular conductive layer 131 are arranged concentrically with the center of the inductor region IR (as shown in FIG. 4) in the first region R1. Furthermore, the third semi-circular winding 113, the fourth semi-circular winding 114, and the tenth semi-circular winding 120 are arranged concentrically with the center of the inductor region IR in the second region R2.

Similarly, in some embodiments, the fifth semi-circular winding 115, the sixth semi-circular winding 116, and the ninth semi-circular winding 119 are arranged concentrically with the center of the inductor region IR in the first region R1. Furthermore, the seventh semi-circular winding 117, the eighth semi-circular winding 118, and the second semi-circular conductive layer 132 are arranged concentrically with the center of the inductor region IR in the second region R2.

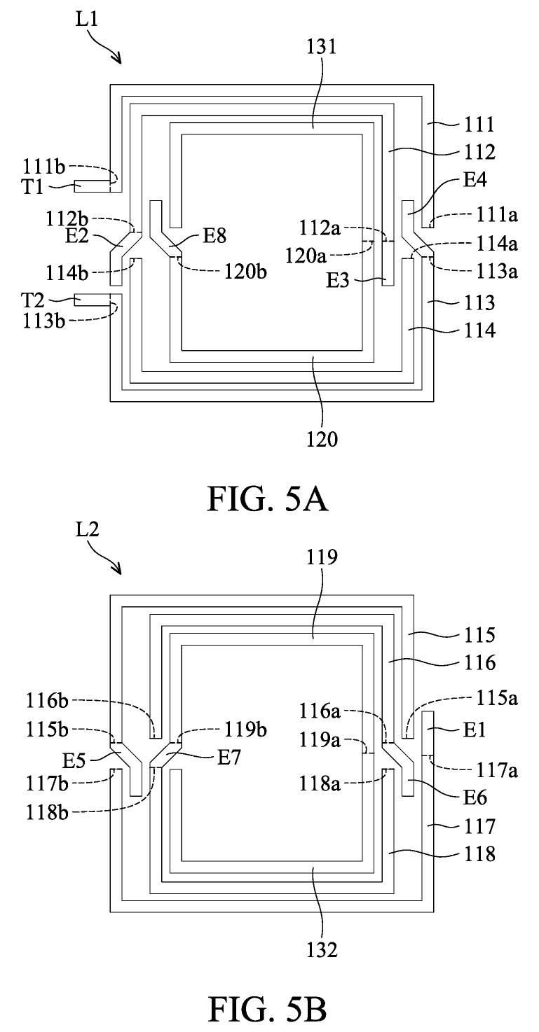

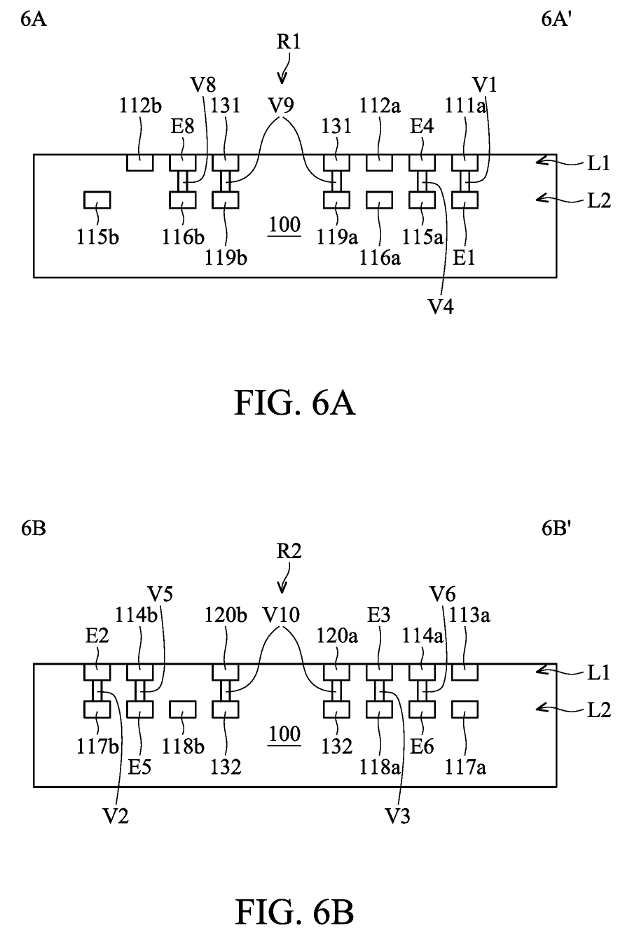

Refer to FIGS. 6A and 6B. FIG. 6A shows a cross-sectional view along line 6A-6A’ in FIG. 4 according to some embodiments of the present disclosure, and FIG. 6B shows a cross-sectional view along line 6B-6B’ in FIG. 4 according to some embodiments of the present disclosure. At the same time, refer to FIGS. 4, 5A and 5B again. In some embodiments, the first semi-circular winding 111, the seventh semi-circular winding 117, the second semi-circular winding 112, the eighth semi-circular winding 118 and the ninth semi-circular winding 119 are electrically connected in sequence, and the third semi-circular winding 113, the fifth semi-circular winding 115, the fourth semi-circular winding 114, the sixth semi-circular winding 116 and the tenth semi-circular winding 120 are electrically connected in sequence. Next, the ninth semi-circular winding 119 and the tenth semi-circular winding 120 are connected to each other to form a spiral inductor in the multilayer-type on-chip inductor structure 20.

In addition, in some embodiments, as viewed from a top-view perspective, the third semi-circular winding 113 and the first semi-circular winding 111 are arranged symmetrically with the center line C1 (as shown in FIG. 1) as the axis of symmetry, and the third semi-circular winding 113 partially overlaps the seventh semi-circular winding 117 on the projection plane. Furthermore, as viewed from a top-view perspective, the sixth semi-circular winding 116 and the eighth semi-circular winding 118 are also arranged symmetrically with the center line C1 as the axis of symmetry. In addition, as viewed from a top-view perspective, the first semi-circular conductive layer 131 and the tenth semi-circular winding 120 are arranged symmetrically with the center line C1 as the axis of symmetry, and the first semi-circular conductive layer 131 overlaps the ninth semi-circular winding 119 on the projection plane. Furthermore, as viewed from a top-view perspective, the second semi-circular conductive layer 132 and the ninth semi-circular winding 119 are arranged symmetrically with the center line C1 as the symmetry axis, and the second semi-circular conductive layer 132 overlaps the tenth semi-circular winding 120 on the projection plane.

As shown in FIGS. 4 and 5B, a conductive extending portion E7 is disposed at the second level L2 of the dielectric layer 100, and extends from the end portion 118b of the eighth semi-circular winding 118 along the oblique direction to the first region R1 as viewed from a top-view perspective. The conductive extending portion E7 extending along the oblique direction is connected to the end portion 119b of the ninth semi-circular winding 119, so that the eighth semi-circular winding 118 is electrically connected to the ninth semi-circular winding 119.

Next, as shown in FIGS. 4, 5A, 5B and 6A, a conductive extending portion E8 is disposed at the first level L1 of the dielectric layer 100, and extends from the end portion 120b of the tenth semi-circular winding 120 along the zigzag direction to the first region R1 as viewed from a top-view perspective. The conductive extending portion E8 extending along the zigzag direction partially overlaps the end portion 116b of the sixth semi-circular winding 116 on the projection plane. Furthermore, a plug structure V8 is disposed in the first region R1 of the dielectric layer 100. The plug structure V8 is disposed between the conductive extending portion E8 and the end portion 116b of the sixth semi-circular winding 116 and is connected thereto. As a result, the tenth semi-circular winding 120 is electrically connected to the sixth semi-circular winding 116.

As shown in FIGS. 4 and 6A, a plug structure V9 is disposed in the first region R1 of the dielectric layer 100 and is connected between the first semi-circular conductive layer 131 at the first level L1 and the ninth semi-circular winding 119 at the second level L2. The plug structure V9 includes a plurality of conductive plugs. These conductive plugs are disposed between the first semi-circular conductive layer 131 and the ninth semi-circular winding 119 and connected thereto. As a result, the first semi-circular conductive layer 131 is electrically connected to the ninth semi-circular winding 119. As viewed from a top-view perspective, the conductive plugs in the plug structure V9 are arranged from one end portion of the first semi-circular conductive layer 131 to the other end portion of the first semi-circular conductive layer 131.

As shown in FIGS. 4 and 6B, a plug structure V10 is disposed in the second region R2 of the dielectric layer 100 and is connected between the second semi-circular conductive layer 132 at the second level L2 and the tenth semi-circular winding 120 at the first level L1. Similarly, the plug structure V10 includes a plurality of conductive plugs. These conductive plugs are disposed between the second semi-circular conductive layer 132 and the tenth semi-circular winding 120 and connected thereto. As a result, the second semi-circular conductive layer 132 is electrically connected to the tenth semi-circular winding 120. As viewed from a top-view perspective, the conductive plugs in the plug structure V10 are arranged from one end portion of the second semi-circular conductive layer 132 to the other end portion of the second semi-circular conductive layer 132.

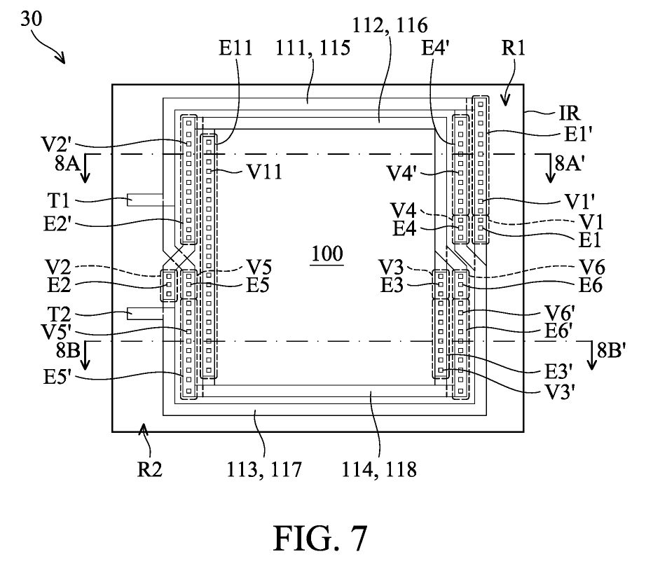

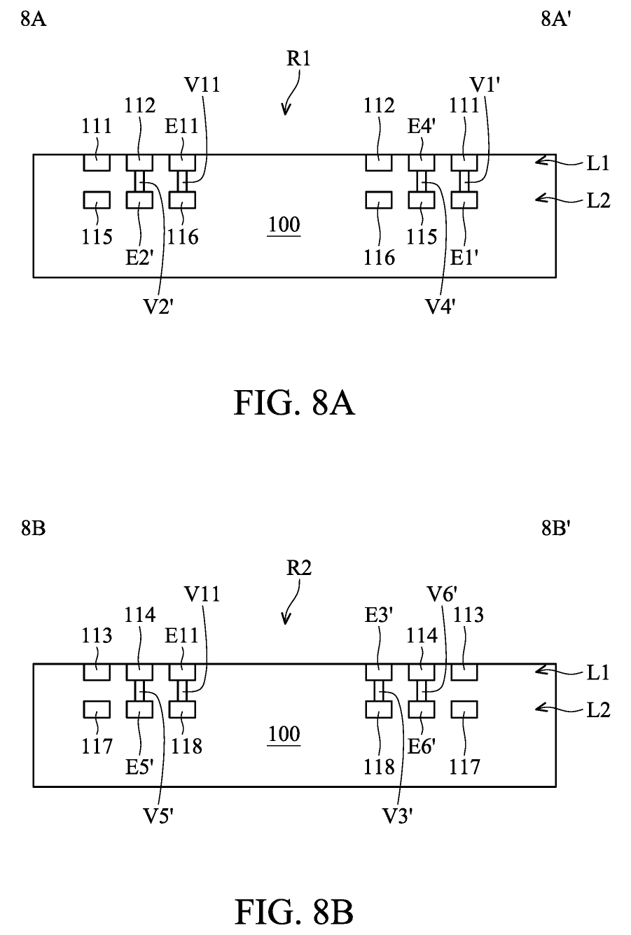

Refer to FIGS. 7, 8A and 8B. FIG. 7 shows a plan view of a multilayer-type on-chip inductor structure 30 according to some embodiments of the present disclosure. Furthermore, FIG. 8A illustrates a cross-sectional view along line 8A-8A’ in FIG. 7 according to some embodiments of the present disclosure, and FIG. 8B illustrates a cross-sectional view along line 8B-8B’ in FIG. 7 according to some embodiments of the present disclosure. Herein, elements in FIGS. 7, 8A and 8B that are the same as or similar to those of the multilayer-type on-chip inductor structure 10 in FIGS. 1, 3A and 3B are labeled with the same or similar reference numbers as in FIGS. 1, 3A and 3B and their descriptions may be omitted.

In some embodiments, the multilayer-type on-chip inductor structure 30 is similar to the multilayer-type on-chip inductor structure 10 in FIGS. 1, 3A and 3B. For example, the upper windings and the lower windings in the multilayer-type on-chip inductor structure 30 may be the same as the upper windings shown in FIG. 2A and the lower windings shown in FIG. 2B, respectively.

However, unlike the multi-layer on-chip inductor structure 10, the multi-layer on-chip inductor structure 30 has additional conductive layers and additional plug structures corresponding to the non-overlapping portion between the upper windings and the lower windings. As a result, the winding stacking layers formed of the semi-circular windings in the upper windings and the lower windings and the corresponding additional conductive layers and additional plug structures increases the cross section of the winding of the inductor. Here, the term “cross section” refers to an area of the semi-circular winding stacking layer perpendicular to the current direction in the inductor. As a result, the inductor can reduce the conductor loss because portions of the winding have a thicker effective thickness, thereby improving the quality factor (Q value) of the inductor and improving the inductor performance.

In some embodiments, additional conductive layers and additional plug structures may be optionally provided, and conductive lengthening portions may also be optionally provided to increase the extension length of the conductive extending portion and the arrangement length of conductive plugs in a corresponding plug structure. In other words, the overlapping area of the upper or lower semi-circular winding and its corresponding conductive extending portion, corresponding conductive lengthening portion and corresponding plug structure on the projection plane is no longer limited to the end portion of the corresponding semi-circular winding. As a result, the overlapping area of the conductive extending portion and its corresponding semi-circular winding can be maximized by providing the conductive lengthening portions. Similarly, the winding stacking layer formed of the semi-circular winding and its corresponding conductive extending portion, corresponding conductive lengthening portion and corresponding plug structure can increase the cross section (or effective thickness) of the winding of the inductor, thereby further reducing the conductor loss.

In some embodiments, a first conductive layer E2’ is disposed at the second level L2 of the dielectric layer 100, as shown in FIGS. 7 and 8A. Refer to FIG. 7, as viewed from a top-view perspective, the first conductive layer E2’ is disposed in the first region R1, and the first conductive layer E2’ partially overlaps a portion of the second semi-circular winding 112 on the projection plane and is electrically connected thereto. Since the portion of the second semi-circular winding 112 does not overlap the sixth semi-circular winding 116 on the projection plane, a first conductive layer E2’ is provided, and a plug structure V2’ is disposed in the dielectric layer 100 between the first conductive layer E2’ and the portion of the second semi-circular winding 112 to form a winding stack layer where the first conductive layer E2’ and the portion of the second semi-circular winding 112 are electrically connected to each other. As a result, the cross section (or effective thickness) of the winding of the inductor can be increased.

Similarly, in some embodiments, a second conductive layer E11 is additionally disposed at the first level L1 of the dielectric layer 100, as shown in FIGS. 7, 8A and 8B. Refer to the seventh FIG. 7, as viewed from a top-view perspective, the second conductive layer E11 extends from the first region R1 to the second region R2, and the second conductive layer E11 partially overlaps a portion of the sixth semi-circular winding 116 and a portion of the eighth semi-circular winding 118 on the projection plane. Similarly, the portion of the sixth semi-circular winding 116 and the portion of the eighth semi-circular winding 118 do not respectively overlap the second semi-circular winding 112 and the fourth semi-circular winding 114 on the projection plane. Therefore, the second conductive layer E11 is additionally provided and the plug structure V11 is additionally provided in the dielectric layer 100 between the second conductive layer E11 and the sixth semi-circular winding 116 and the eighth semi-circular winding 118, so as to form a winding stack layer where the second conductive layer E11, the sixth semi-circular winding 116 and the eighth semi-circular winding 118 are electrically connected to each other. As a result, the cross section of the winding of the inductor can be increased.

In some embodiments, conductive lengthening portions are also provided in the multilayer-type on-chip inductor structure 30 to increase the extension length of the conductive extending portion and the arrangement length of conductive plugs in a corresponding plug structure. As viewed from a top-view perspective, a conductive lengthening portion E1’ disposed at the second level L2 of the dielectric layer 100 extends from the conductive extending portion E1 (which extends from the end portion 117a of the seventh semi-circular winding 117 and is indicated by FIG. 2B) to the first region R1 along a straight line direction. Furthermore, the arrangement length of conductive plugs in a corresponding plug structure V1’ also extends beyond the end portion 111a of the first semi-circular winding 111 (indicated by FIG. 2A) along with the conductive lengthening portion E1’, as shown in FIGS. 7 and 8A.

As viewed from a top-view perspective, a conductive lengthening portion E3’ at the first level L1 of the dielectric layer 100 extends from the conductive extending portion E3 (which extends from the end portion 112a of the second semi-circular winding 112 and is indicated by FIG. 2A) to the second region R2 along a straight line direction. Furthermore, the arrangement length of conductive plugs in a corresponding plug structure V3’ also extends beyond the end portion 118a of the eighth semi-circular winding 118 (indicated by FIG. 2B) along with the conductive lengthening portion E3’, as shown in FIGS. 7 and 8B.

As viewed from a top-view perspective, a conductive lengthening portion E4’ at the first level L1 of the dielectric layer 100 extends from the conductive extending portion E4 (which extends from the end portion 113a of the third semi-circular winding 113 and is indicated by FIG. 2A) to the first region R1 along a straight line direction. Furthermore, the arrangement length of conductive plugs in a corresponding plug structure V4’ also extends beyond the end portion 115a (indicated by FIG. 2B) of the fifth semi-circular winding 115 along with the conductive lengthening portion E4’, as shown in FIGS. 7 and 8A.

As viewed from a top-view perspective, the conductive lengthening portion E5’ at the second level L2 of the dielectric layer 100 extends from the conductive extending portion E5 (which extends from the end portion 115b of the fifth semi-circular winding 115 and is indicated by FIG. 2B) to the second region R2 along a straight line direction. Furthermore, the arrangement length of conductive plugs in a corresponding plug structure V5’ also extends beyond the end portion 114b (indicated by FIG. 2A) of the fourth semi-circular winding 114 along with the conductive lengthening portion E5’, as shown in FIGS. 7 and 8B.

As viewed from a top-view perspective, the conductive lengthening portion E6’ at the second level L2 of the dielectric layer 100 extends from the conductive extending portion E6 (which extends from the end portion 116a of the sixth semi-circular winding 116 and is indicated by FIG. 2B) to the second region R2 along a straight line direction. Furthermore, the arrangement length of conductive plugs in a corresponding plug structure V6’ also extends beyond the end portion 114a of the fourth semi-circular winding 114 (indicated by FIG. 2A) along with the conductive lengthening portion E6’, as shown in FIGS. 7 and 8B.

The extension length of the conductive lengthening portion and the corresponding arrangement length of the corresponding plug structure exceed the end portion of the semi-circular winding to be overlapped, so that the overlapping area of the conductive extending portion and its corresponding semi-circular winding can be maximized via the conductive lengthening portion. As a result, the winding stack layer formed of the semi-circular winding and the corresponding conductive extending portion and the corresponding plug structure can increase the cross section (or effective thickness) of the winding of the inductor, thereby reducing the conductor loss.

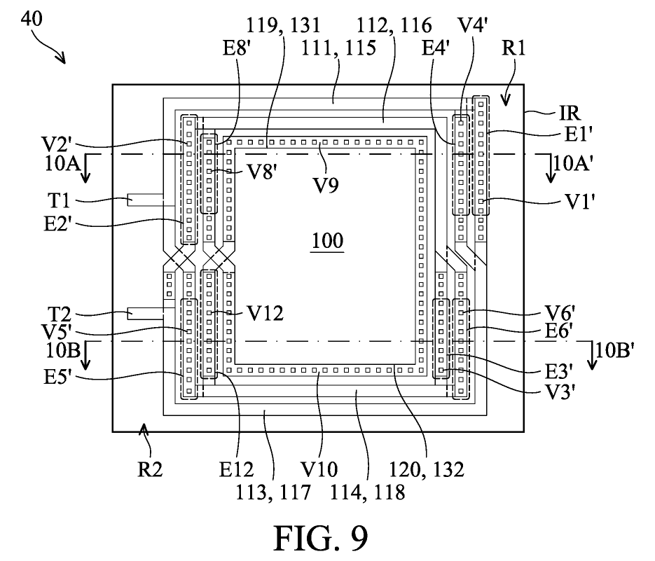

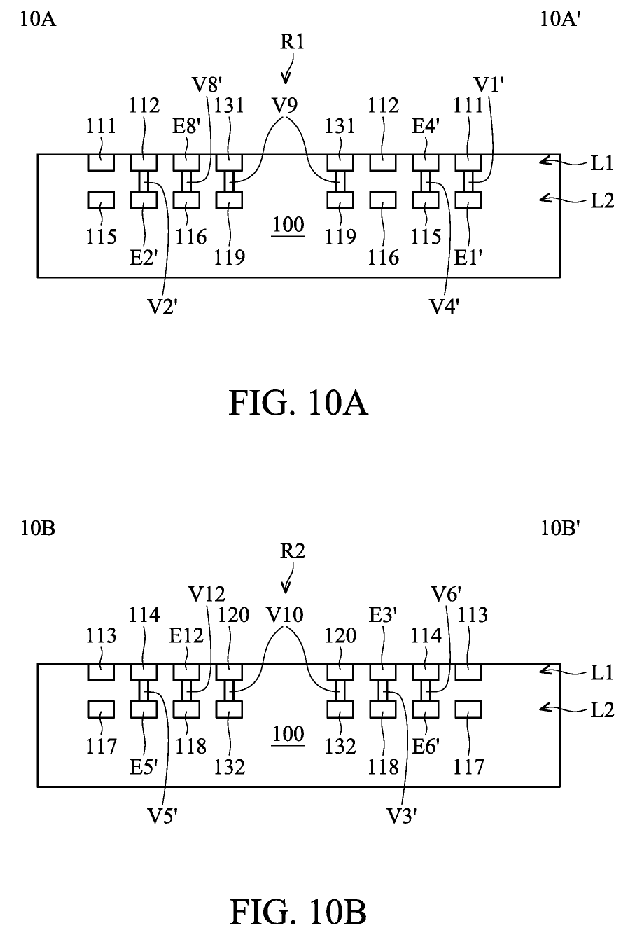

Refer to FIGS. 9, 10A and 10B. FIG. 9 is a plan view of a multilayer-type on-chip inductor structure 40 according to some embodiments of the present disclosure. Furthermore, FIG. 10A is a cross-sectional view along line 10A-10A’ in FIG. 9 according to some embodiments of the present disclosure, and FIG. 10B is a cross-sectional view along line 10B-10B’ in FIG. 9 according to some embodiments of the present disclosure. Herein, elements in FIGS. 9, 10A and 10B that are the same as or similar to the multilayer-type on-chip inductor structure 20 in FIGS. 4, 6A and 6B or the multilayer-type on-chip inductor structure 30 in FIGS. 7, 8A and 8B are labeled with the same or similar reference numbers as in FIGS. 4, 6A and 6B or 7, 8A and 8B and their descriptions may be omitted.

In some embodiments, the multilayer-type on-chip inductor structure 40 is similar to the multilayer-type on-chip inductor structure 20 in FIGS. 4, 6A and 6B. For example, the upper windings and the lower windings in the multilayer-type on-chip inductor structure 40 may be the same as the upper windings shown in FIG. 5A and the lower windings shown in FIG. 5B, respectively.

However, unlike the multilayer-type on-chip inductor structure 20, the non-overlapping portions between the upper windings and the lower windings in the multilayer-type on-chip inductor structure 40 are provided with additional conductive layer and additional plug structures that are similar to those in the multilayer-type on-chip inductor structure 30 in FIGS. 7, 8A and 8B.

In some embodiments, a first conductive layer E2’ is disposed at the second level L2 of the dielectric layer 100, as shown in FIGS. 9 and 10A. As viewed from a top-view perspective, the first conductive layer E2’ is disposed in the first region R1, and the first conductive layer E2’ partially overlaps the second semi-circular winding 112 on the projection plane and is electrically connected thereto. Furthermore, a plug structure V2’ is disposed in the dielectric layer 100 between the first conductive layer E2’ and the second semi-circular winding 112.

In some embodiments, a second conductive layer E12 is disposed at the first level L1 of the dielectric layer 100, as shown in FIGS. 9 and 10B. As viewed from a top-view perspective, the second conductive layer E12 is disposed in the second region R2, and the second conductive layer E12 partially overlaps the eighth semi-circular winding 118 on the projection plane. Since a portion of the eighth semi-circular winding 118 does not overlap the fourth semi-circular winding 114 on the projection plane, an additional second conductive layer E12 is provided and an additional plug structure V12 is provided in the dielectric layer 100 between the second conductive layer E12 and the portion of the eighth semi-circular winding 118 to form a winding stack layer where the second conductive layer E12 and the eighth semi-circular winding 118 are electrically connected to each other. As a result, the cross section of the winding of the inductor can be further increased.

In some embodiments, similar to the multilayer-type on-chip inductor structure 30 in FIGS. 7, 8A and 8B, the multilayer-type on-chip inductor structure 40 can also optionally provide a conductive lengthening portion to increase the extension length of the conductive extending portion and the arrangement length of conductive plugs in a corresponding plug structure. As a result, the cross section (or effective thickness) of the winding of the inductor can also be increased, thereby further reducing the conductor loss.

In some embodiments, similar to the multilayer-type on-chip inductor structure 30 (as shown in FIG. 7), conductive lengthening portions are also provided in the multilayer-type on-chip inductor structure 40 to increase the extension length of the conductive extending portion and the arrangement length of conductive plugs in a corresponding plug structure. More specifically, as viewed from a top-view perspective, a conductive lengthening portion E1’ at the second level L2 of the dielectric layer 100 extends from the conductive extending portion E1 (indicated by FIG. 5B) along a straight line to the first region R1. Furthermore, the arrangement length of conductive plugs in a corresponding plug structure V1’ also extends beyond the end portion 111a of the first semi-circular winding 111 (indicated by FIG. 5A) along with the conductive lengthening portion E1’, as shown in FIGS. 9 and 10A.

As viewed from a top-view perspective, a conductive lengthening portion E3’ at the first level L1 of the dielectric layer 100 extends from the conductive extending portion E3 (indicated by FIG. 5A) to the second region R2 along a straight line direction. Furthermore, the arrangement length of conductive plugs in a corresponding plug structure V3’ also extends beyond the end portion 118a (indicated by FIG. 5B) of the eighth semi-circular winding 118 along with the conductive lengthening portion E3’, as shown in FIGS. 9 and 10B.

As viewed from a top-view perspective, a conductive lengthening portion E4’ at the first level L1 of the dielectric layer 100 extends from the conductive extending portion E4 (indicated by FIG. 5A) to the first region R1 along a straight line direction. Furthermore, the arrangement length of conductive plugs in a corresponding plug structure V4’ also extends beyond the end portion 115a (indicated by FIG. 5B) of the fifth semi-circular winding 115 along with the conductive lengthening portion E4’, as shown in FIGS. 9 and 10A.

As viewed from a top-view perspective, a conductive lengthening portion E5’ at the second level L2 of the dielectric layer 100 extends from the conductive extending portion E5 (indicated by FIG. 5B) to the second region R2 along a straight line direction. Furthermore, the arrangement length of conductive plugs in a corresponding plug structure V5’ also extends beyond the end portion 114b (indicated by FIG. 5A) of the fourth semi-circular winding 114 along with the conductive lengthening portion E5’, as shown in FIGS. 9 and 10B.

As viewed from a top-view perspective, a conductive lengthening portion E6’ at the second level L2 of the dielectric layer 100 extends from the conductive extending portion E6 (indicated by FIG. 5B) to the second region R2 along a straight line direction. Furthermore, the arrangement length of conductive plugs in a corresponding plug structure V6’ also extends beyond the end portion 114a (indicated by FIG. 5A) of the fourth semi-circular winding 114 along with the conductive lengthening portion E6’, as shown in FIGS. 9 and 10B.

As viewed from a top-view perspective, a conductive lengthening portion E8’ at the first level L1 of the dielectric layer 100 extends from the conductive extending portion E8 (indicated by FIG. 5A) to the first region R1 along a straight line direction. Furthermore, the arrangement length of conductive plugs in a corresponding plug structure V8’ also extends beyond the end portion 116b (indicated by FIG. 5B) of the sixth semi-circular winding 116 along with the conductive lengthening portion E8’, as shown in FIGS. 9 and 10A.

The extension length of the conductive lengthening portion and the arrangement length of the plugs in the corresponding plug structure exceed the end portion of the semi-circular winding to be overlapped, so that the overlapping area of the conductive extending portion and its corresponding semi-circular winding can be maximized via the conductive lengthening portion. As a result, the winding cross-sectional area (or effective thickness) of the inductor can be increased, thereby reducing the conductor loss.

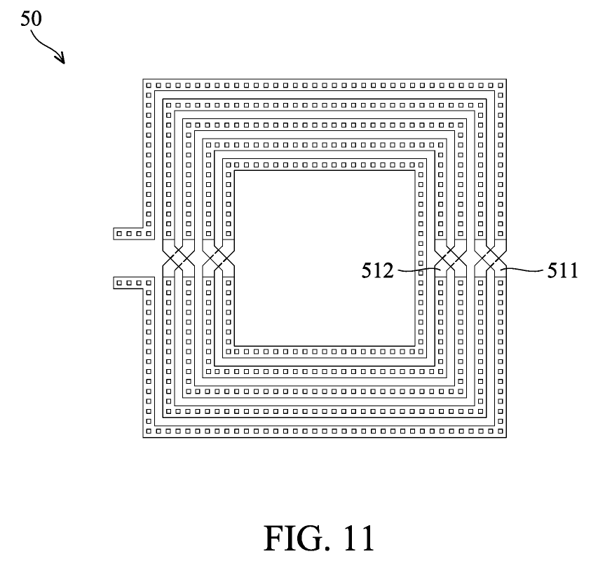

According to the multilayer-type on-chip inductor structures in the foregoing embodiments, in the winding path from the first input/output terminal portion to the center of the inductor, the adjacent semi-circular windings are electrically connected by alternately using the conductive extending portion and the corresponding plug structure that extend along the straight direction and the conductive extending portion and the corresponding plug structure that extend along the zigzag direction. Furthermore, in the winding path from the second input/output terminal portion to the center of the inductor, the adjacent semi-circular windings are electrically connected by using the conductive extending portion and the corresponding plug structure that extend along the zigzag direction. As a result, the plane size and manufacturing cost of the inductor are effectively reduced. For example, taking the multilayer-type on-chip inductor structure 20 (e.g., a double-layer on-chip inductor structure) in the embodiment of FIG. 4 as an example, its equivalent inductance value is even better than the inductance value of the conventional double-layer inductor 50 in which the upper windings 511 and the lower windings 512 respectively have 5 turns of winding and occupy 5 turns of winding area (as shown in FIG. 11). However, the winding area occupied by the double-layer inductor shown in FIG. 4 is smaller than the winding area occupied by the double-layer inductor 50 shown in FIG. 11. As a result, the size of the inductor can be reduced.

Furthermore, according to the multilayer-type on-chip inductor structure of the foregoing embodiments, additional conductive layers and corresponding plug structures can be provided in the non-overlapping region between the upper windings and the lower windings to form a winding stacking layer, thereby reducing the conductor loss of the winding of the inductor element. As a result, the quality factor of the inductor and the inductor performance can be improved. In addition, the multilayer-type on-chip inductor structures of the foregoing embodiments have structures in which adjacent metal layers overlap each other, so that the coupling factor (coupling factor K) between the inductor from the input/output terminal portion T1 to the center point and the inductor from the input/output terminal portion T2 to the center point can be improved.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A multilayer-type on-chip inductor structure, comprising:
a dielectric layer having an inductor region divided into a first region and a second region by a center line;
first to fourth semi-circular windings arranged at a first level of the dielectric layer; and
fifth to eighth semi-circular windings arranged at a second level lower than the first level of the dielectric layer,
wherein the first and second semi-circular windings at the first level and the fifth and sixth semi-circular windings at the second level are arranged concentrically in the first region, and the third and fourth semi-circular windings at the first level and the seventh and eighth semi-circular windings at the second level are arranged concentrically in the second region,
wherein the first, seventh, second and eighth semi-circular windings are electrically connected in sequence, and the third, fifth, fourth and sixth semi-circular windings are electrically connected in sequence, and
wherein as viewed from a top-view perspective, the third semi-circular winding is arranged symmetrically with the first semi-circular winding, and the third semi-circular winding partially overlaps the seventh semi-circular winding.

2. The structure as claimed in claim 1, further comprising:
a first conductive extending portion extending from a first end portion of the seventh semi-circular winding to the first region;
a first plug structure disposed in the first region of the dielectric layer between the first conductive extending portion and a first end portion of the first semi-circular winding and connected thereto, so that the first semi-circular winding is electrically connected to the seventh semi-circular winding;
a second conductive extending portion extending from a first end portion of the second semi-circular winding to the second region;
a second plug structure disposed in the second region of the dielectric layer between a second conductive extending portion and a second end portion of the seventh semi-circular winding and connected thereto, so that the seventh semi-circular winding is electrically connected to the second semi-circular winding;
a third conductive extending portion extending from a second end portion of the second semi-circular winding to the second region;
a third plug structure disposed in the second region of the dielectric layer between the third conductive extending portion and a first end portion of the eighth semi-circular winding and connected thereto, so that the second semi-circular winding is electrically connected to the eighth semi-circular winding;
a fourth conductive extending portion extending from a first end portion of the third semi-circular winding to the first region;
a fourth plug structure disposed in the first region of the dielectric layer between the fourth conductive extending portion and a first end portion of the fifth semi-circular winding and connected thereto, so that the third semi-circular winding is electrically connected to the fifth semi-circular winding;
a fifth conductive extending portion extends from a second end portion of the fifth semi-circular winding to the second region;
a fifth plug structure disposed in the second region of the dielectric layer between the fifth conductive extending portion and a first end portion of the fourth semi-circular winding and connected thereto, so that the fifth semi-circular winding is electrically connected to the fourth semi-circular winding;
a sixth conductive extending portion extending from a first end portion of the sixth semi-circular winding to the second region; and
a sixth plug structure disposed in the second region of the dielectric layer between the sixth conductive extending portion and a second end portion of the fourth semi-circular winding and connected thereto, so that the fourth semi-circular winding is electrically connected to the sixth semi-circular winding.

3. The structure as claimed in claim 1, further comprising:
a ninth semi-circular winding disposed at the second level of the dielectric layer and arranged concentrically in the first region with the fifth and sixth semi-circular windings, wherein the ninth semi-circular winding is electrically connected to the eighth semi-circular winding; and
a tenth semi-circular winding disposed at the first level of the dielectric layer and arranged concentrically in the second region with the third and fourth semi-circular windings, wherein the tenth semi-circular winding is electrically connected to the sixth semi-circular winding.

4. The structure as claimed in claim 3, further comprising:
a seventh conductive extending portion extending from a first end portion of the eighth semi-circular winding to a first end portion of the ninth semi-circular winding;
an eighth conductive extending portion extending from a first end portion of the tenth semi-circular winding to the first region; and
an eighth plug structure disposed in the first region of the dielectric layer between the eighth conductive extending portion and a first end portion of the sixth semi-circular winding and connected thereto, so that the tenth semi-circular winding is electrically connected to the sixth semi-circular winding.

5. The structure as claimed in claim 4, further comprising:
a first semi-circular conductive layer extending from a second end portion of the tenth semi-circular winding to the first region, wherein as viewed from a top-view perspective, the first semi-circular conductive layer and the tenth semi-circular winding are symmetrically arranged, and the first semi-circular conductive layer overlaps the ninth semi-circular winding.

6. The structure as claimed in claim 5, further comprising:
a ninth plug structure disposed in the first region of the dielectric layer and connected between the first semi-circular conductive layer and the ninth semi-circular winding, wherein the ninth plug structure comprises a plurality of conductive plugs, and wherein as viewed from a top-view perspective, the plurality of conductive plugs of the ninth plug structure are arranged from a first end portion of the first semi-circular conductive layer to a second end portion of the first semi-circular conductive layer.

7. The structure as claimed in claim 6, further comprising:
a second semi-circular conductive layer extending from a second end portion of the ninth semi-circular winding to the second region, wherein as viewed from a top-view perspective, the second semi-circular conductive layer and the ninth semi-circular winding are arranged symmetrically, and the second semi-circular conductive layer overlaps the tenth semi-circular winding; and
a tenth plug structure disposed in the second region of the dielectric layer and connected between the second semi-circular conductive layer and the tenth semi-circular winding.

8. The structure as claimed in claim 7, wherein the tenth plug structure includes a plurality of conductive plugs, and wherein as viewed from a top-view perspective, the plurality of conductive plugs of the tenth plug structure are arranged from a first end portion of the second semi-circular conductive layer to a second end portion of the second semi-circular conductive layer.

9. The structure as claimed in claim 1, wherein as viewed from a top-view perspective, the sixth semi-circular winding and the eighth semi-circular winding are arranged symmetrically, and the sixth semi-circular winding partially overlaps the second semi-circular winding.

10. A multilayer-type on-chip inductor structure, comprising:
a dielectric layer having an inductor region divided into a first region and a second region by a center line;
first to fourth semi-circular windings arranged at the first level of the dielectric layer;
fifth to eighth semi-circular windings arranged at the second level lower than the first level of the dielectric layer; and
a first conductive layer arranged at the second level of the dielectric layer;
wherein the first, second, fifth and sixth semi-circular windings are disposed in the first region, and the third, fourth, seventh and eighth semi-circular windings are disposed in the second region,
wherein the first, seventh, second and eighth semi-circular windings are electrically connected in sequence, and the third, fifth, fourth and sixth semi-circular windings are electrically connected in sequence,
wherein as viewed from a top-view perspective, the third semi-circular winding and the first semi-circular winding are symmetrically arranged, and the third semi-circular winding partially overlaps the seventh semi-circular winding, and
wherein as viewed from a top-view perspective, the first conductive layer is disposed in the first region, and the first conductive layer overlaps a portion of the second semi-circular winding and is electrically connected thereto.

11. The structure as claimed in claim 10, further comprising:
a first conductive extending portion extending from a first end portion of the seventh semi-circular winding to the first region;
a first plug structure disposed in the first region of the dielectric layer, overlapping the first conductive extending portion and a first end portion of the first semi-circular winding as viewed from a top-view perspective, and connected thereto, so that the first semi-circular winding is electrically connected to the seventh semi-circular winding;
a second conductive extending portion extending from a first end portion of the second semi-circular winding to the second region;
a second plug structure disposed in the second region of the dielectric layer, overlapping the second conductive extending portion and a second end portion of the seventh semi-circular winding as viewed from a top-view perspective, and connected thereto, so that the seventh semi-circular winding is electrically connected to the second semi-circular winding;
a third conductive extending portion extending from a second end portion of the second semi-circular winding to the second region; and
a third plug structure disposed in the second region of the dielectric layer, overlapping the third conductive extending portion and a first end portion of the eighth semi-circular winding as viewed from a top-view perspective, and connected thereto, so that the second semi-circular winding is electrically connected to the eighth semi-circular winding.

12. The structure as claimed in claim 11, further comprising:
a first conductive lengthening portion extending from the first conductive extending portion along a straight line direction to the first region, wherein the first plug structure extends above the first conductive lengthening portion; and
a third conductive lengthening portion extending from the third conductive extending portion along a straight line direction to the second region, wherein the third plug structure extends below the third conductive lengthening portion.

13. The structure as claimed in claim 10, further comprising:
a fourth conductive extending portion extending from a first end portion of the third semi-circular winding to the first region;
a fourth plug structure disposed in the first region of the dielectric layer, overlapping the fourth conductive extending portion and a first end portion of the fifth semi-circular winding as viewed from a top-view perspective, and connected thereto, so that the third semi-circular winding is electrically connected to the fifth semi-circular winding;
a fifth conductive extending portion extending from a second end portion of the fifth semi-circular winding to the second region;
a fifth plug structure disposed in the second region of the dielectric layer, overlapping the fifth conductive extending portion and a first end portion of the fourth semi-circular winding as viewed from a top-view perspective, and connected thereto, so that the fifth semi-circular winding is electrically connected to the fourth semi-circular winding;
a sixth conductive extending portion extending from a first end portion of the sixth semi-circular winding to the second region; and
a sixth plug structure disposed in the second region of the dielectric layer, overlapping the sixth conductive extending portion and a second end portion of the fourth semi-circular winding as viewed from a top-view perspective, and connected thereto, so that the fourth semi-circular winding is electrically connected to the sixth semi-circular winding.

14. The structure as claimed in claim 13, further comprising:
a fourth conductive lengthening portion extending from the fourth conductive extending portion to the first region along a straight line direction, wherein the fourth plug structure extends below the fourth conductive lengthening portion;
a fifth conductive lengthening portion extending from the fifth conductive extending portion to the second region along a straight line direction, wherein the fifth plug structure extends above the fifth conductive lengthening portion; and
a sixth conductive lengthening portion extending from the sixth conductive extending portion to the second region along a straight line direction, wherein the sixth plug structure extends above the sixth conductive lengthening portion.

15. The structure as claimed in claim 11, further comprising:
a second conductive layer disposed at the first level of the dielectric layer, wherein as viewed from a top-view perspective, the second conductive layer extends from the first region to the second region, and the second conductive layer overlaps a portion of the sixth semi-circular winding and a portion of the eighth semi-circular winding.

16. The structure as claimed in claim 11, further comprising:
a ninth semi-circular winding disposed at the second level of the dielectric layer, and arranged concentrically with the fifth and sixth semi-circular windings at the second level of the dielectric layer in the first region, wherein the ninth semi-circular winding is electrically connected to the eighth semi-circular winding; and
a tenth semi-circular winding disposed at the first level of the dielectric layer, and arranged concentrically with the third and fourth semi-circular windings at the first level of the dielectric layer in the second region, wherein the tenth semi-circular winding is electrically connected to the sixth semi-circular winding.

17. The structure as claimed in claim 16, further comprising:
a seventh conductive extending portion extending from a first end portion of the eighth semi-circular winding to a first end portion of the ninth semi-circular winding;
an eighth conductive extending portion extending from a first end portion of the tenth semi-circular winding to the first region; and
an eighth plug structure disposed in the first region of the dielectric layer, overlapping the eighth conductive extending portion and a first end portion of the sixth semi-circular winding in a top view, and connected thereto, so that the tenth semi-circular winding is electrically connected to the sixth semi-circular winding.

18. The structure as claimed in claim 16, further comprising:
a first semi-circular conductive layer extending from a second end portion of the tenth semi-circular winding to the first region, wherein as viewed from a top-view perspective, the first semi-circular conductive layer and the tenth semi-circular winding are symmetrically arranged, and the first semi-circular conductive layer overlaps the ninth semi-circular winding;
a second semi-circular conductive layer extending from a second end portion of the ninth semi-circular winding to the second region, wherein as viewed from a top-view perspective, the second semi-circular conductive layer and the ninth semi-circular winding are symmetrically arranged, and the second semi-circular conductive layer overlaps the tenth semi-circular winding; and
a ninth plug structure and a tenth plug structure, respectively disposed in the first region and the second region of the dielectric layer, wherein the ninth plug structure is connected between the first semi-circular conductive layer and the ninth semi-circular winding, and the tenth plug structure is connected between the second semi-circular conductive layer and the tenth semi-circular winding.

19. The structure as claimed in claim 16, further comprising:
a second conductive layer disposed at the first level of the dielectric layer and in the second region, wherein as viewed from a top-view perspective, the second conductive layer overlaps a portion of the eighth semi-circular winding;
an eighth conductive extending portion, extending from a first end portion of the tenth semi-circular winding to the first region; and
an eighth plug structure disposed in the first region of the dielectric layer, overlapping the eighth conductive extending portion and a first end portion of the sixth semi-circular winding as viewed from a top-view perspective, and connected thereto, so that the sixth semi-circular winding is electrically connected to the tenth semi-circular winding.

20. The structure as claimed in claim 19, further comprising:
an eighth conductive lengthening portion extending from the eighth conductive extending portion to the first region along a straight line direction, wherein the eighth plug structure extends below the eighth conductive lengthening portion.
